(19) United States
(12) Patent Application Publication
(10) Pub. No.: US 2010/0125377 A1
(43) Pub. Date: May 20, 2010

(54) APPARATUS TO TEST SEMICONDUCTOR DEVICE AND METHOD OF TESTING SEMICONDUCTOR DEVICE USING THE SAME

(75) Inventors: Min-Woo KIM, Cheonan-si (KR); Byung-Rong Min, Hwaseong-si (KR); Deog-Jong Hwang, Cheongju-si (KR); Bae-Ki Lee, Cheonan-si (KR); Sang-HAN Yun, Asan-si (KR)

Correspondence Address: STANZIONE & KIM, LLP, 919 18TH STREET, N.W., SUITE 440, WASHINGTON, DC, 20006, US

(73) Assignees: Samsung Electronics Co., Ltd.; SEMILINE Co., Ltd.

(21) Appl. No.: 12/618,865

(22) Filed: Nov. 16, 2009

(30) Foreign Application Priority Data
Nov. 17, 2008 (KR) 2008-114213

(51) Int. Cl. G05D 23/00; G01R 31/02

(52) U.S. Cl. 700/300; 324/765

(57) ABSTRACT

An apparatus to test a semiconductor device includes a chamber defining an inner space to receive a plurality of semiconductor devices, a temperature control apparatus connected to the chamber and configured to heat or cool the chamber to a predetermined level, and a control module to transmit an electrical signal to the temperature control apparatus to heat or cool an inner space of the chamber. As a result, the semiconductor devices can be exposed to heating and cooling environments having set test temperature values to selectively perform a test.

### CROSS-REFERENCE TO RELATED APPLICATIONS

This application claims priority under 35 U.S.C. §119 from Korean Patent Application No. 10-2008-0114213, filed on Nov. 17, 2008, which is incorporated herein by reference in its entirety.

### BACKGROUND

1. Field of the Invention

Example embodiments relate to an apparatus to test a semiconductor device and a method of testing a semiconductor device using the same. Other example embodiments relate to an apparatus to test a semiconductor device and a method of testing a semiconductor device using the same that are capable of exposing semiconductor devices to heating and cooling environments having set test temperatures to selectively perform tests.

2. Description of the Related Art

In general, after manufacture, a semiconductor module is mounted on a mother board of a computer and then passed through a semiconductor module mounting test area to be inspected for defects. The semiconductor module mounting test is a test to determine whether the semiconductor module operates normally in environments of a low temperature (about 10° C.), a normal temperature (about 25° C.), and a high temperature (about 55° C.).

The semiconductor module mounting test is performed in a state in which mother substrates, on which semiconductor modules are mounted, are loaded in a chamber.

A conventional semiconductor module mounting test apparatus includes a chamber in which a test process is performed, a heating part to heat the chamber, a cooling part to cool the chamber, and a controller to control operations of the respective components.

The conventional heating part and cooling part are separated from each other to provide independent environments to heat and cool the semiconductor modules.

Therefore, when the temperature environment test is performed on the semiconductor device using the conventional semiconductor module mounting test, the process flow may be complicated depending on the high temperature and low temperature test processes.

In addition, the conventional heating part includes a heater and a fan to provide hot air into the chamber. The cooling part uses a conventional coolant, which includes a compressor, a condenser, and an evaporator to provide cold air into the chamber.

However, when the conventional high temperature test is performed, external air, from which moisture is not removed, is introduced through the fan to be heated by the heater, and then supplied into the chamber. Therefore, power consumption may be increased due to use of the heater and the fan.

In addition, when the low temperature test is performed, the external air, from which moisture is not removed, is introduced through the cooler to lower the temperature, and then supplied into the chamber.

Therefore, condensation is generated in the chamber due to introduction of the moist air, causing inferiority of the semiconductor devices during the test.

Further, since the use of Freon gas, which has been widely used as the conventional coolant for coolers, i.e., cooling parts, is limited due to environmental regulations, costs due to use of novel coolants compliant with the environmental regulations are being increased. Furthermore, noises are excessively generated from a compressor during operation of the cooling part, causing problems related to the noises.

### SUMMARY

Example embodiments provide an apparatus to test a semiconductor device and a method of testing a semiconductor device using the same that are capable of selectively performing heating and cooling environment tests of semiconductor devices in a single chamber.

Example embodiments also provide an apparatus to test a semiconductor device and a method of testing a semiconductor device using the same that are capable of recognizing a set test temperature to form a heating or cooling test environment in the chamber and test semiconductor devices.

Additional aspects and utilities of the present general inventive concept will be set forth in part in the description which follows and, in part, will be obvious from the description, or may be learned by practice of the general inventive concept.

Features and/or utilities of the present general inventive concept may be realized by an apparatus to test a semiconductor device, the apparatus including a chamber having a certain space in which a plurality of semiconductor devices are disposed, a temperature conversion module connected to the chamber and configured to heat or cool the chamber to increase the temperature in the chamber to a certain level, and a control module to transmit an electrical signal to the temperature conversion module to selectively heat or cool an inner space of the chamber.

The chamber may be located on an upper surface of a main body or mounting apparatus. A lower part of the chamber may be exposed to the upper surface of the main body. A board may be installed on the upper surface of the main body to transmit an electrical signal from inside the chamber to the exterior, and sockets may be fixedly installed on the board to electrically connect the semiconductor devices to the board.

One side of the chamber may be connected to the main body by a rotary member. The rotary member may include a first hinge end on the one side of the chamber, a second hinge end connected to the main body, and a cylinder to connect the first hinge end to the second hinge end and to longitudinally expand/contract by receiving an electrical signal from the control module.

A gap may be formed between an upper end surface of the main body and a lower end surface of the chamber.

The temperature conversion module may include a hot air supplier to provide hot air heated to a certain temperature into the chamber, and a cold air supplier to provide cold air cooled to a certain temperature into the chamber.

In addition, the control module may include a selector configured to selectively operate any one of the hot air supplier and the cold air supplier.

A reference temperature value may be previously set in the control module, and the control module may operate the hot air supplier when a test temperature value is higher than the reference temperature value and operate the cold air suppler when the test temperature value is lower than the reference temperature value.

The hot air supplier may include a first air compressor to compress external air, a housing to receive the compressed air from the first air compressor, a suction pipe to connect the first air compressor to the housing, a heater located in the housing to receive an electrical signal from the control module to heat the compressed air to a certain temperature, and an exhaust pipe to connect the housing to the interior of the chamber to provide the heated compressed air into the chamber. The cold air supplier may include a second air compressor to compress external air, and a vortex tube to receive the compressed air from the second air compressor to be rotated at a certain speed to form flow paths having different temperatures and to supply the compressed air cooled of a certain temperature into the chamber.

The vortex tube may include a vortex rotary chamber having a rotary space disposed in the chamber and configured to rotate the compressed air introduced from the second air compressor at a certain rotational speed, a compressed air supply pipe configured to introduce the compressed air from the second air compressor into the vortex rotary chamber, a hot air discharge pipe configured to expose the rotary space of the vortex rotary chamber to the exterior of the chamber and guide a first vortex stream generated by rotation from the rotary space, an adjustment valve installed at an end of the hot air discharge pipe and configured to receive an electrical signal from the control module and selectively discharge the first vortex stream to the exterior of the chamber, and a cold air discharge pipe configured to expose the rotary space of the vortex rotary chamber to the interior of the chamber and guide a second vortex stream generated by rotation of the rotary space and directed in a different direction than the first vortex stream.

Further, a silencer may be installed at an end of the discharge pipe. The silencer may include a silencer body having a flow hole that is gradually reduced from the end of the discharge pipe, and a sound-absorbing material buried in the silencer body.

Furthermore, a diffuser having a plurality of discharge holes may be further installed at the end of the discharge pipe. The discharge pipe may be connected to a center part of the diffuser, the discharge holes may be radially disposed with respect to the center part, and the diameters of the discharge holes may be sequentially increased from the center part.

In addition, the discharge pipe may be connected to the discharge pipe, and an opening valve may be further installed at the connected position to selectively expose an air flow path of the exhaust pipe or the cold air discharge pipe to the interior of the chamber as the control module selects the hot air supplier or the cold air supplier.

Features and/or utilities of the present general inventive concept may also be realized by a method of testing a semiconductor device, the method including positioning a plurality of semiconductor devices in an inner space of the chamber, and performing a test by receiving an electrical signal from a control module and selectively heating or cooling an inner space of the chamber using a temperature conversion module connected to the chamber.

Positioning the semiconductor devices may include rotating and opening the chamber, which is located on an upper surface of a main body, using a rotary member connected to the chamber and the main body, positioning the semiconductor devices on a board on the upper surface of the main body to be electrically connected to the board, and positioning the chamber at its original position using the rotary member so that a certain gap is located between a lower surface of the chamber and an upper surface of the main body to expose the inner space of the chamber to the exterior of the chamber.

In addition, the performing of the test may include selecting any one of a hot air supplier of the temperature conversion module configured to provide hot air heated to a certain temperature into the chamber and a cold air supplier of the temperature conversion module configured to provide cold air cooled to a certain temperature into the chamber using a selector electrically connected to the control module and setting a test temperature value formed in the inner space of the chamber using the control module and the selected hot air supplier or the cold air supplier.

Further, the performing of the test may include setting a reference temperature value using the control module, and operating the hot air supplier of the temperature conversion module configured to provide hot air heated to a certain temperature into the chamber when the set test temperature value is equal to or higher than the reference temperature value and operating the cold air supplier of the temperature conversion module configured to provide cold air cooled to a certain temperature into the chamber when the test temperature value is equal to or lower than the reference temperature value, using the control module.

Furthermore, the hot air supplier may include a first air compressor configured to compress external air, a housing configured to receive the compressed air from the first air compressor, a suction pipe configured to connect the first air compressor to the housing, a heater disposed in the housing and configured to receive an electrical signal from the control module to heat the compressed air to a certain temperature, and an exhaust pipe configured to connect the housing to the interior of the chamber to provide the heated compressed air into the chamber. The cold air supplier may include a second air compressor configured to compress external air, and a vortex tube configured to receive the compressed air from the second air compressor to be rotated at a certain speed to form flow paths having different temperatures and supply the compressed air cooled to a certain temperature into the chamber. The vortex tube may include a vortex rotary chamber having a rotary space disposed in the chamber and configured to rotate the compressed air introduced from the second air compressor at a certain rotational speed, a compressed air supply pipe configured to introduce the compressed air from the second air compressor into the vortex rotary chamber, a hot air discharge pipe configured to expose the rotary space of the vortex rotary chamber to the exterior of the chamber and guide a first vortex stream generated by rotation from the rotary space, an adjustment valve installed at an end of the hot air discharge pipe and configured to receive an electrical signal from the control module and selectively discharge the first vortex stream to the exterior of the chamber, and a cold air discharge pipe configured to expose the rotary space of the vortex rotary chamber to the interior of the chamber and guide a second vortex stream generated by rotation of the rotary space and directed in a different direction than the first vortex stream. The cold air discharge pipe may be connected to the exhaust pipe, and an opening valve may be further installed at the connected position. An air flow path of the exhaust pipe or the cold air discharge pipe may be selectively exposed in the chamber using the opening valve operated by receiving an electrical signal of the control module as the hot air supplier or the cold air supplier is selected.

Features and/or utilities of the present general inventive concept may also be realized by a semiconductor device test apparatus including a chamber to receive at least one semiconductor device and a temperature control apparatus to supply hot air and cold air, respectively, into the chamber.

The chamber may include an upper portion comprising side walls and a top, and a lower portion including an upper surface of a mounting apparatus. The upper portion may be mounted to the lower portion by a rotatable hinge, and the upper portion may be separated from the lower portion by a gap capable of passing air from inside the chamber to outside the chamber.

The temperature control apparatus may include at least one air compressor, a hot air supplier, a cold air supplier, and a diffuser. The hot air supplier may include a housing having a heater therein to heat the air from the air compressor and an exhaust pipe to output the heated air from the housing into the chamber. The cold air supplier may include a vortex rotary device including a vortex air chamber to receive compressed air from the air compressor, to generate a plurality of air currents within the vortex rotary device, to output hot air outside the chamber, and to output cold air into the chamber. The diffuser may receive at least one of hot air and cold air from the hot air supplier and cold air supplier, respectively, and output the hot air and cold air into the chamber.

The temperature control apparatus may be mounted to the upper portion of the chamber.

The vortex rotary device may include a cold air discharge pipe. The temperature control apparatus may further include a connection pipe to connect the cold air discharge pipe and the exhaust pipe and an air control valve to respectively output air from each of the hot air supplier and the cold air supplier into the chamber.

The semiconductor device test apparatus may further include a sensor located inside the chamber to determine a temperature within the chamber and a controller to control operation of the hot air supplier and cold air supplier based upon the temperature within the chamber and predetermined test settings, and to control opening and closing of the chamber by controlling rotation of the rotatable hinge.

### BRIEF DESCRIPTION OF THE DRAWINGS

The above and/or other aspects of the present general inventive concept will become apparent and more readily appreciated from the following description of the exemplary embodiments, taken in conjunction with the accompanying drawings, in which:

Example embodiments are described in further detail below with reference to the accompanying drawings. It should be understood that various aspects of the drawings may have been exaggerated for clarity.

FIG. 1 is a cross-sectional view of an apparatus for testing a semiconductor device in accordance with an example embodiment of the present general inventive concept;

FIG. 2 is a cross-sectional view showing a state in which a chamber is rotated and opened;

FIG. 3 is a cross-sectional view of a vortex tube of FIG. 1;

FIG. 4 is a block diagram showing the configuration of the apparatus for testing a semiconductor device of FIG. 1;

FIG. 5 is a cross-sectional view of another example of the apparatus for testing a semiconductor device in accordance with an example embodiment of the present general inventive concept;

FIG. 6 is a cross-sectional view showing a state in which a chamber of FIG. 5 is rotated and opened;

FIG. 7 is a block diagram showing the configuration of the apparatus for testing a semiconductor device of FIG. 5;

FIG. 8 is a plan view of a diffuser in accordance with an example embodiment of the present general inventive concept;

FIG. 9 is a flowchart showing a method of testing a semiconductor device in accordance with an example embodiment of the present general inventive concept; and

FIG. 10 is a flowchart showing another method of testing a semiconductor device in accordance with an example embodiment of the present general inventive concept.

### DETAILED DESCRIPTION OF THE EMBODIMENTS

Various example embodiments will now be described more fully with reference to the accompanying drawings in which some example embodiments are shown. In the drawings, the thicknesses of layers and regions may be exaggerated for clarity. Like reference numerals refer to the like elements throughout. The embodiments are described below in order to explain the present general inventive concept by referring to the figures.

Detailed illustrative embodiments are disclosed herein. However, specific structural and functional details disclosed herein are merely representative for purposes of describing example embodiments. This general inventive concept, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the general inventive concept.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” “on” versus “directly on,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present general inventive concept is not limited to example embodiments described.

Example embodiments relate to a semiconductor device and methods of fabricating the same. Other example embodiments relate to a semiconductor device having a trench isolation region and methods of fabricating the same.

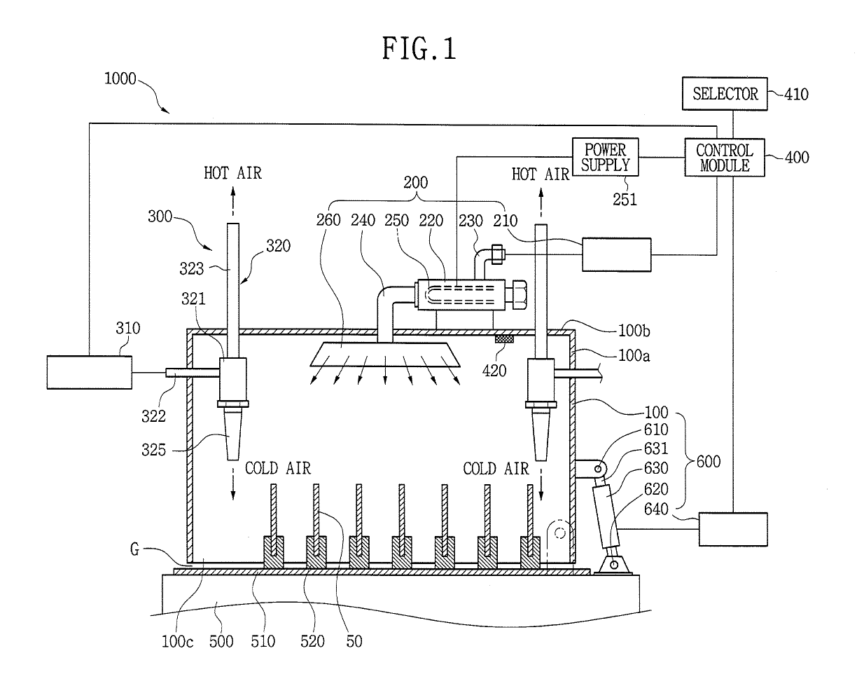

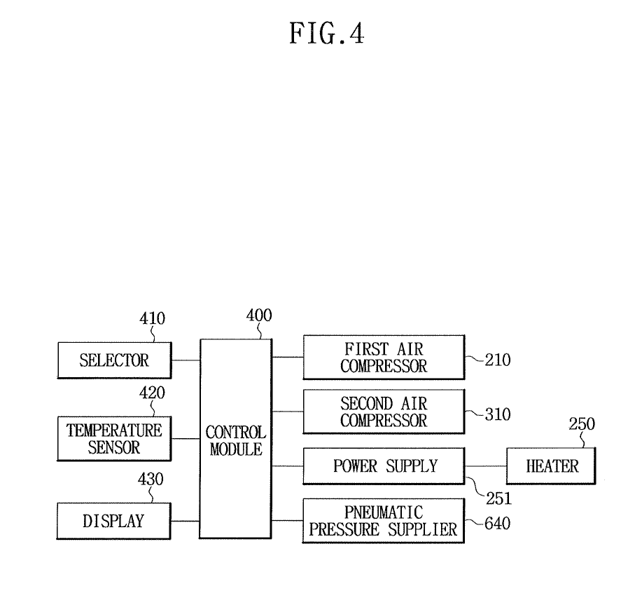

First, the configuration of the apparatus to test a semiconductor device in accordance with the present general inventive concept will be described with reference to FIGS. 1 to 4.

The apparatus to test a semiconductor device includes a chamber 100 having side walls 100a and a top 100b defining a space within the chamber 100. A lower end 100c of the chamber may have an open portion that opens toward a mounting apparatus 500, or main body. The side walls 100a, top 100b, and mounting apparatus 500 may enclose the space within the chamber. The upper portion of the chamber 100 may be positioned above the mounting apparatus 500 so that a gap G is located between the upper portion of the chamber 100 and the mounting apparatus 500 when the chamber 100 is in a closed position. During operation, a plurality of semiconductor devices 50 may be positioned on the mounting apparatus 500 within the chamber 100. A temperature control apparatus including a hot air supplier 200 and a cold air supplier 300 may be connected to the chamber 100 to heat or cool the inner space of the chamber 100 to a certain temperature value. A control module 400 may control the temperature control apparatus by transmitting an electrical signal to the temperature control apparatus to heat and cool the inner space of the chamber 100.

A board 510 may be mounted on the upper surface of the mounting apparatus 500 to transmit electrical signals from the semiconductor devices 50 to circuitry outside the chamber. Sockets 520 may be installed on the board 510 to electrically connect the semiconductor devices 50 to the board 510.

The chamber 100 may be mounted to the upper surface of the mounting apparatus 500 by a rotary member 600. The rotary member 600 may include a first hinge end 610 connected to an outer side surface of the chamber 100, a second hinge end 620 mounted to the mounting apparatus 500, and a cylinder 630 connecting the first hinge end 610 to the second hinge end 620. The cylinder 630 may longitudinally expand/contract to open and close the chamber 100 by receiving an electrical signal from the control module 400.

The cylinder 630 may include a cylinder shaft 631, and may be connected to a pneumatic pressure supplier 640. The pneumatic pressure supplier 640 may receive an electrical signal from the control module 400 and supply a pneumatic pressure to the cylinder 630 to expand/contract the cylinder shaft 631.

The hot air supplier 200 of the temperature control apparatus may provide hot air heated to a certain temperature into the chamber 100, and a cold air supplier 300 may provide cold air cooled to a certain temperature into the chamber 100.

Furthermore, the control module 400 may include a selector 410 to select one of the hot air supplier 200 and the cold air supplier 300 to operate. The selector 410 may be a programmed electronic device or a physical apparatus that automatically selects which supplier 200, 300 to operate, or it may be a manual selector to receive an input from a user. The control module 400 may include electronic components including processors, logic circuitry, memory, and interfaces to receive signals and/or inputs from the selector and the temperature control apparatus, and to output signals to the temperature control apparatus and other components of the semiconductor test apparatus 1000.

The hot air supplier 200 of the temperature control apparatus may include a first air compressor 210 to compress external air, a housing 220 to receive the compressed air from the first air compressor 210, a suction pipe 230 to connect the first air compressor 210 to the housing 220, and a power supply 251 electrically connected to the control module 400. A heater 250 may be located in the housing 220 to be electrically connected to the power supply 251 and to receive an electrical signal from the control module 400 to heat the compressed air to a certain temperature. An exhaust pipe 240 may connect the housing 220 to the interior of the chamber 100 to provide the heated compressed air into the chamber 100.

The cold air supplier 300 may include a second air compressor 310 to compress external air and a vortex tube 320 to receive the compressed air from the second air compressor 310 to be rotated at a certain speed to form flow paths having different temperatures and to supply the compressed air cooled to a certain temperature into the chamber 100.

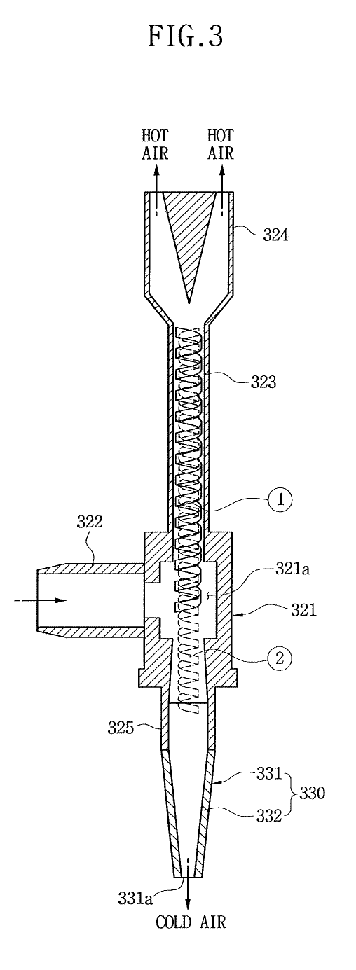

As illustrated in FIG. 3, the vortex tube 320 may include a vortex rotary chamber 321 in the chamber 100 and may have a rotary space 321a to rotate the compressed air introduced from the second air compressor 310 at a certain speed. A compressed air supply pipe 322 may introduce the compressed air from the second air compressor 310 into the vortex rotary chamber 321. A hot air discharge pipe 323 may expose the rotary space of the vortex rotary chamber 321 to the exterior of the chamber 100 and may guide a first vortex stream \textcircled{1} generated by rotation from the rotary space. A regulation valve 324 installed at an end of the hot air discharge pipe 323 may receive an electrical signal from the control module 400 to vary the discharge of the first vortex stream \textcircled{1} to the exterior of the chamber 100. A cold air discharge pipe 325 may expose the rotary space of the vortex rotary chamber 321 to the interior of the chamber 100 and may guide a second vortex stream \textcircled{2} generated by rotation from the rotary space in a direction different from the first vortex stream \textcircled{1}.

In addition, a silencer 330 may be installed at an end of the cold air discharge pipe 325. The silencer 330 may include a silencer body 331 having a flow hole 331a that has the same area as the discharge pipe 325 at the point where the silencer 330 connects to the cold air discharge pipe 325 and gradually decreases in diameter from the end of the cold air discharge pipe 325 to the flow hole 331a. The silencer body 331 may be made of, or may include, a sound-absorbing material 332.

Referring to the hot air supplier 200, a diffuser 260, illustrated in FIG. 8, may be installed at an end of the exhaust pipe 240. The diffuser 260 has a plurality of discharge holes 261 to discharge heated air from the exhaust pipe 240. The exhaust pipe 240 may be connected to a center part of the diffuser 260, and the discharge holes 261 may extend radially from the center part. The discharge holes 261 may have diameters that increase from the center part outward. For example, where Dn represents a diameter of an outermost discharge hole 261 and D1 represents a diameter of a center-most discharge hole 261, D1< . . . <Dn. Increasing the diameter of the discharge holes 261 from the center outward aids in evenly diffusing the air from the exhaust pipe 240, since it is more difficult for air to exit the narrower discharge holes 261 at the center of the diffuser 260 where the air from the exhaust pipe 240 has a higher air pressure than at an outer end of the diffuser 260.

The first air compressor 210 may be further connected to a moisture removing apparatus (not shown) to remove moisture from external air to a predetermined level before passing the air into the chamber 100. The air, from which the moisture is removed, may then be compressed with the first air compressor 210, and the compressed air may be provided to the vortex tube 320. Therefore, the cold air supplied into the chamber 100 may have no moisture or may have a moisture level below a predetermined threshold.

Hereinafter, operation of the apparatus to test a semiconductor device and a method of testing a semiconductor device using the same in accordance with the present general inventive concept will be described.

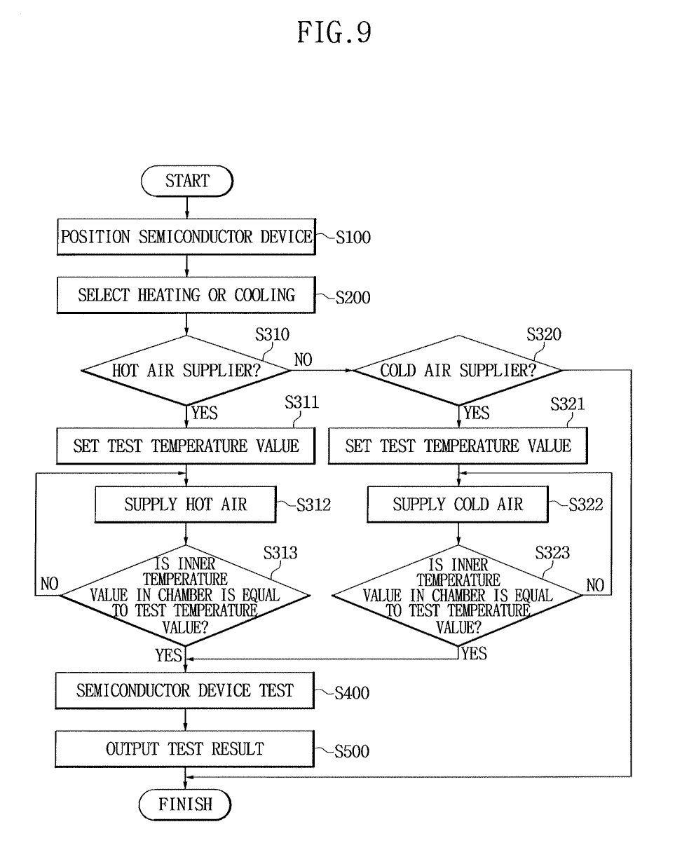

Referring to FIGS. 1 to 4, 8, and 9, a semiconductor device positioning step S100 is performed to position a plurality of semiconductor devices 50 in an inner space of a chamber 100.

In the semiconductor device positioning step S100, the chamber 100 may be rotated and opened using a rotary member 600 attached to a side wall 100b of the chamber 100 and mounted on the mounting apparatus 500.

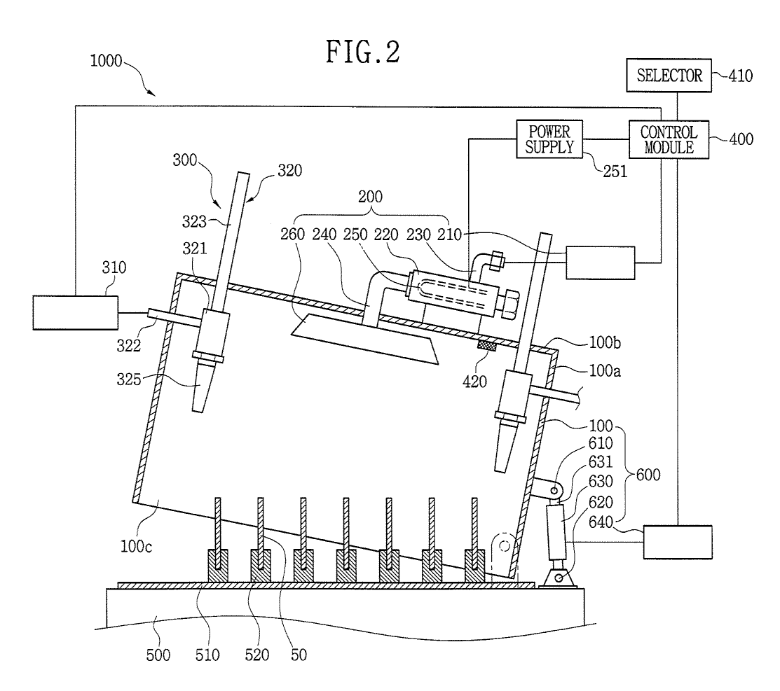

A control module 400 may a pneumatic pressure supplier 640, and the pneumatic pressure supplier 640 may supply a pneumatic pressure to a cylinder 630 to expand and contract a cylinder shaft 631 of the cylinder 630 to a certain length as shown in FIG. 2. The cylinder 630 may be a double acting cylinder in which two cylinder shafts expand and contract from both ends of the cylinder 630.

As the cylinder shaft 631 is contracted toward the cylinder 630, a first hinge end 610 connected to an end of the cylinder shaft 631 is rotated, and the cylinder 630 is rotated by a second hinge end 620 mounted to the mounting apparatus 500. As a result, the chamber 100 having the first hinge end 610 may be opened as shown in FIG. 2.

While the chamber 100 is opened, the semiconductor devices 50 may be positioned on the board 510 mounted on the upper surface of the mounting apparatus 500. The semiconductor devices may be electrically connected to the board 510.

The board 510 may be electrically connected to the control module 400, and a plurality of sockets 520 may be provided on the board 510. The sockets 520 may receive the semiconductor devices 50 to electrically connect the semiconductor devices 50 to external devices, such as the control module 400.

After the semiconductor devices 50 are inserted into the sockets 520, the chamber 100 is returned to its original position by the rotary member 600. The chamber 100 is returned to its original position by operating the cylinder shaft 631 in a reverse sequence of the above operation.

Specifically, the control module 400 operates the pneumatic pressure supplier 640, and the pneumatic pressure supplier 640 supplies a pneumatic pressure to the cylinder 630 to expand the cylinder shaft 631 of the cylinder 630 to a certain length. Therefore, the chamber 100 is rotated downward to be returned to the original position as shown in FIG. 1.

Since a lower surface of the chamber 100 is separated from the upper surface of the mounting apparatus 500 by a gap G, an inner space of the chamber 100 may be exposed to the exterior of the chamber 100 through the gap G.

Next, a test step S200 is performed to select whether to heat or cool the inner space of the chamber 100 using a temperature control apparatus configured to receive an electrical signal from the control module 400 and connected to the chamber 100.

Specifically, a selector 410 electrically connected to the control module 400 selects one of a hot air supplier 200 of the temperature control apparatus to provide hot air heated to a certain temperature into the chamber 100 and a cold air supplier 300 of the temperature control apparatus o provide cold air cooled to a certain temperature into the chamber 100 (S200).

When the selector 410 selects the hot air supplier 200 (S310), the control module 400 sets a test temperature value set in the inner space of the chamber 100 (S311).

Next, the control module 400 transmits an electrical signal to the hot air supplier 200, and the hot air supplier 200 supplies hot air into the inner space of the chamber 100 (S312).

The above step will be described in detail.

A first compressed air supplier 210 supplies the compressed air into a housing 220 through a suction pipe 230. The compressed air supplied into the housing 220 is heated to a certain temperature by a heater 250 that receives power from and is heated by a power source 251. In addition, the heated compressed air is supplied into the chamber 100 through an exhaust pipe 240.

The compressed air is supplied into the inner space of the chamber 100 through a diffuser 260 at the end of the exhaust pipe 240. The diffuser 260 has a plurality of discharge holes 261. As discussed above, the discharge holes 261 have diameters that gradually increase from a center part of the diffuser 260 toward an outer periphery thereof. According to the above configuration, the compressed air may flow into the inner space of the chamber 100 through the plurality of discharge holes 261 at a uniform pressure.

The hot air introduced into the chamber 100 may flow toward the exterior of the chamber through a gap G formed between a lower surface 100c of the chamber 100 and an upper surface of the mounting apparatus 500.

In addition, a temperature sensor 420 installed in the chamber 100 detects a temperature value of the inner space of the chamber 100, and transmits the detected temperature value to the control module 400. The control module 400 determines whether the detected temperature value of the inner space of the chamber 100 is equal to a predetermined test temperature value (S313).

The control module 400 maintains operation of the hot air supplier 200 for a predetermined period of time when the detected temperature value of the inner space of the chamber 100 is equal to a predetermined test temperature, and receives an electrical signal from the semiconductor devices 50 through a board 510 mounted on the mounting apparatus 500 (S400). The predetermined period of time is a semiconductor device test time set in the control module 400.

In addition, the control module 400 may output results of an electrical test result via a display 430 based on the electrical signals transmitted from the semiconductor devices 50 (S500). The test results may include data that the semiconductor devices 50 operate normally in an atmosphere with a predetermined test temperature value for a predetermined period of time.

After the completion of the semiconductor device test by the hot air supplier 200, the control module 400 may stop an operation of the hot air supplier 200, and open the chamber 100 using the rotary member 600 as shown in FIG. 2 to set a state in which the tested semiconductor devices 50 can be removed from sockets 520, thereby completing the test step.

Meanwhile, when the selector 410 in accordance with the present general inventive concept selects the cold air supplier 300 (S320), the control module 400 sets a cold test temperature value in the inner space of the chamber 100 (S321).

Then, the control module 400 transmits an electrical signal to the cold air supplier 300, and the cold air supplier 300 supplies cold air into the inner space of the chamber 100 (S322).

Specifically, the control module 400 transmits an electrical signal to a second air compressor 310, and the second air compressor 310 generates compressed air, which is supplied into a vortex rotary chamber 321 through a compressed air supply pipe 322.

A hot air discharge pipe 323 of a vortex tube 320 is in communication with the exterior of the chamber 100, and a cold air discharge pipe 325 is in communication with the inner space of the chamber 100. The orientations of the hot air discharge pipe 323 and the cold air discharge pipe 325 may be varied depending upon the desired characteristics of the semiconductor device test apparatus 1000.

When the compressed air is supplied through the second air compressor 310 into the vortex rotary chamber 321, the compressed air may be rotated at about one million rpm. This may be referred to as a primary vortex stream \textcircled{1} or primary rotary air.

The primary rotary air \textcircled{1} is discharged through the hot air discharge pipe 323, and the remaining air is returned by a regulation valve 324 to form a secondary vortex stream \textcircled{2} or secondary rotary air and then be discharged through the cold air discharge pipe 325.

At this time, a flow of the secondary rotary air \textcircled{2} passes through a lower pressure region than an inside region of a flow of the primary rotary air \textcircled{1} to lose the amount of heat and then flow through the cold air discharge pipe 325, and then, is discharged into the inner space of the chamber 100 through a silencer 330 installed at an end of the cold air discharge pipe 325.

In the flows of the primary and secondary rotary air \textcircled{1} and \textcircled{2}, since one rotation time of the secondary rotary air \textcircled{2} is equal to that of the primary rotary air \textcircled{1}, an actual moving speed is lower than a moving speed of the primary rotary air \textcircled{1}.

The difference in the moving speeds means that kinetic energy is reduced, and the reduced kinetic energy is converted into heat to increase the temperature of the primary rotary air \textcircled{1} and decrease the temperature of the secondary rotary air \textcircled{2}.

Therefore, the primary rotary air \textcircled{1} finally discharged through the hot air discharge pipe 323 is discharged as hot air heated in comparison with the compressed air, and the secondary rotary air \textcircled{2} discharged through the cold air discharge pipe 325 is discharged as cold air cooled in comparison with the compressed air.

Therefore, the cold air may be supplied into the inner space of the chamber 100 through the vortex tube 320.

The cold air introduced into the inner space of the chamber 100 may flow to the exterior of the chamber 100 through the gap G between the lower surface 100c of the chamber 100 and the upper surface of the mounting apparatus 500.

As discussed above, the temperature sensor 420 installed in the chamber 100 detects a temperature value of the inner space of the chamber 100 and transmits the detected temperature value of the inner space of the chamber 100 to the control module 400. The control module 400 determines whether the detected temperature value of the inner space of the chamber 100 is equal to a predetermined test temperature value (S323).

The control module 400 maintains operation of the cold air supplier 300 for a predetermined period of time when the detected temperature value of the inner space of the chamber 100 is equal to a predetermined test temperature value. The control module 400 receives electrical signals from the semiconductor devices 50 through the board 510 installed on the upper surface of the mounting apparatus 500 (S400). The predetermined period of time is a semiconductor device test time set in the control module 400.

The control module 400 may output an electrical test result through a display 430 based on the electrical signals transmitted from the semiconductor devices 50 (S500). The test result may include data on whether the semiconductor devices 50 operate normally for a predetermined period of time in an atmosphere with a test temperature value.

After the completion of the semiconductor device test by the cold air supplier 200, the control module 400 stops the operation of the hot air supplier 200, and opens the chamber 100 using the rotary member 600 as shown in FIG. 2 to remove the sockets 520 from the chamber 100, thereby completing the test.

Above, the method of selectively operating any one of the hot air supplier 200 and the cold air supplier 300 using the selector 410 electrically connected to the control module 400 has been described.

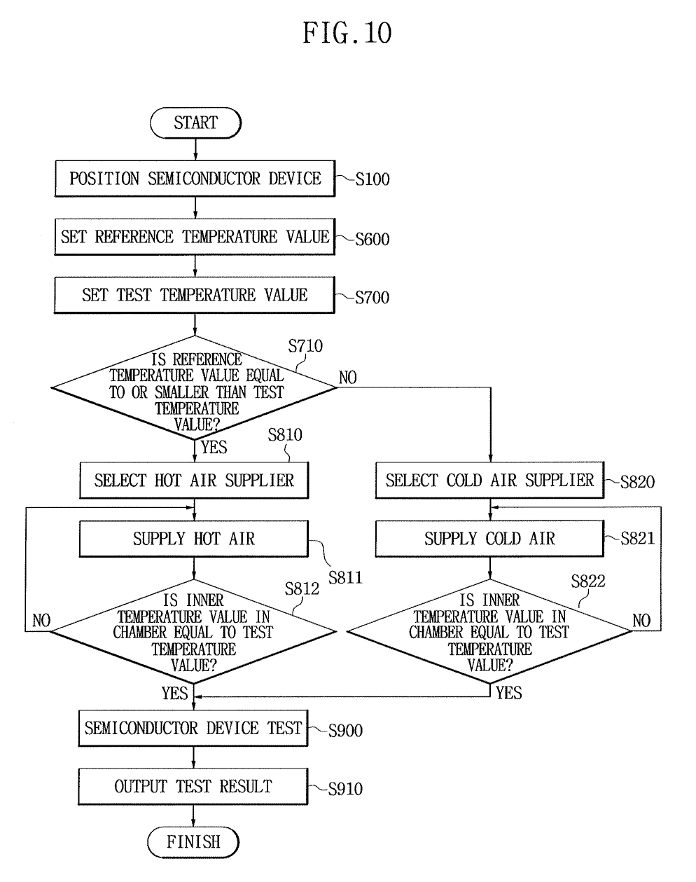

Referring to FIG. 10, after the disposition of the semiconductor devices (S100), a reference temperature value is preset in the control module 400 of the present general inventive concept. The control module 400 may operate the hot air supplier 200 when the set test temperature value is larger than the reference temperature value and the cold air supplier 300 when the test temperature value is lower than the reference temperature value.

The test step may include setting a reference temperature value using the control module 400 (S600), setting a heating or cooling test temperature value to the control module 400 (S700), determining whether the reference temperature value is lower than the test temperature value using the control module 400 (S710), operating the hot air supplier 200 of the temperature control apparatus to provide hot air heated to a certain temperature into the chamber 100 using the control module 400 when the set test temperature value is higher than the reference temperature value (S810), and operating the cold air supplier 300 of the temperature control apparatus to provide cold air cooled to a certain temperature into the chamber 100 when the test temperature value is lower than the reference temperature value (S820).

Since operations of the hot air supplier 200 and the cold air supplier 300 (S810 to S910 and S820 to S910) are the same as described above, detailed description thereof will not be repeated.

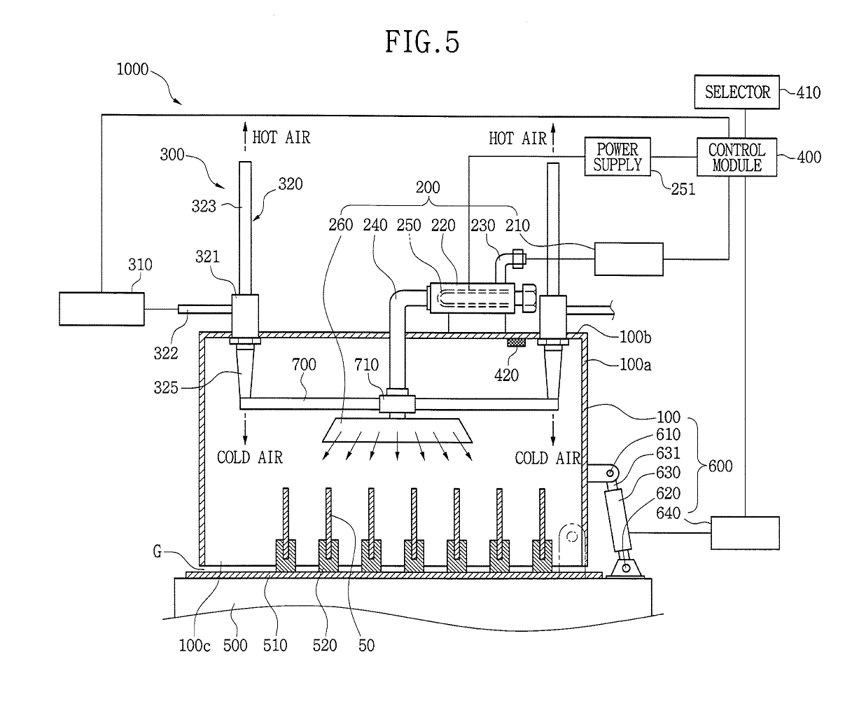

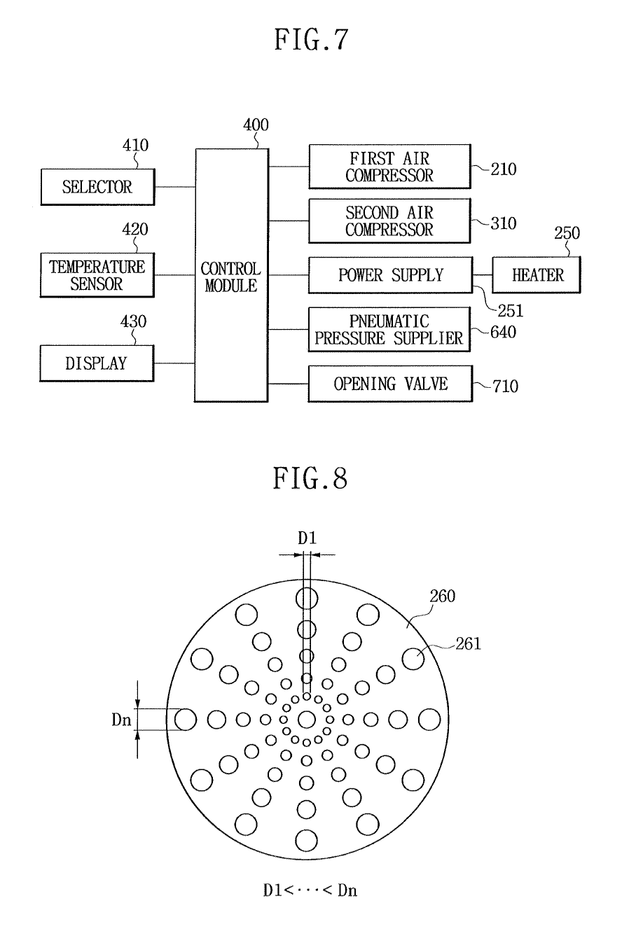

Meanwhile, referring to FIGS. 5 to 7, the cold air discharge pipe 325 of the cold air supplier 300 may be in communication with the exhaust pipe 240 of the hot air supplier 200.

That is, the silencer 330 installed at an end of the cold air discharge pipe 325 may be in communication with an end of the exhaust pipe 240 by a connection pipe 700.

As the hot air supplier 200 or the cold air supplier 300 is selected by the control module 400, an opening valve 710 connecting the connection pipe 700 to the exhaust pipe 240 may expose an air flow path of the exhaust pipe 240 or the cold air discharge pipe 325 to the interior of the chamber 100.

The opening valve 710 may be a three-way valve configured to receive an electrical signal from outside the chamber to change directions of flow paths. For example, the opening valve 710 may be controlled by the control module 400.

As described above, if the selector 410 selects the hot air supplier 200 or the hot air supplier 200 is operated when the test temperature value set in the control module 400 is higher than the predetermined reference temperature value, the control module 400 may transmit an electrical signal to the opening valve 710 to supply the hot air into the chamber 100.

Specifically, the opening valve 710 closes the flow path of the cold air discharge pipe 325 and opens the flow path of the exhaust pipe 240 to supply the hot air flowing through the exhaust pipe 240 into the inner space of the chamber 100 through the diffuser 260.

In addition, if the selector 410 selects the cold air supplier 300 or the cold air supplier 300 is operated when the test temperature value set in the control module 400 is lower than the predetermined reference temperature value, the control module 400 may transmit an electrical signal to the opening valve 710 to supply the cold air into the chamber 100.

That is, the opening valve 710 closes the flow path of the exhaust pipe 240 and opens the flow path of the cold air discharge pipe 325 to supply the cold air flowing through the cold air discharge pipe 325 into the inner space of the chamber 100 through the diffuser 260.

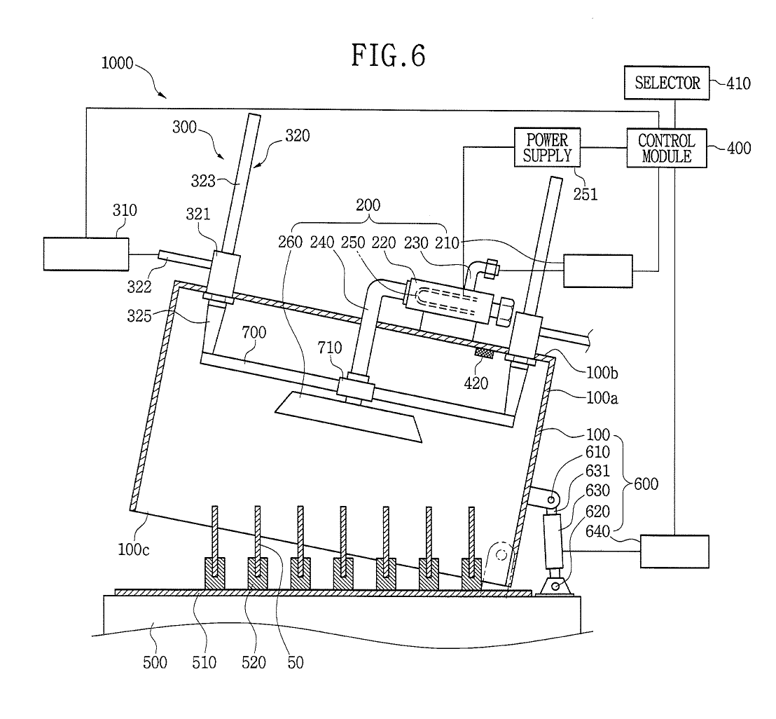

Therefore, referring to FIGS. 5 and 6, both the cold air and the hot air may be uniformly supplied into the inner space of the chamber 100 through the discharge holes 261 of the diffuser 260 having different diameters.

As a result, the hot air or the cold air may be supplied into the chamber 100 through the single diffuser 260.

As can be seen from the foregoing, it is possible to selectively perform heating and cooling environment tests of semiconductor devices in a single chamber.

In addition, it is possible to recognize a set test temperature value to form heating or cooling test environments in the chamber, thereby testing semiconductor devices.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this general inventive concept as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

Although a few embodiments of the present general inventive concept have been illustrated and described, it will be appreciated by those skilled in the art that changes may be made in these embodiments without departing from the principles and spirit of the general inventive concept, the scope of which is defined in the appended claims and their equivalents.

What is claimed is:

1. An apparatus to test a semiconductor device, comprising:
a chamber to receive therein a plurality of semiconductor devices;
a temperature control apparatus connected to the chamber to heat and to cool the chamber to predetermined temperature levels; and
a control module to transmit an electrical signal to the temperature conversion module to selectively heat or cool an inner space of the chamber.

2. The apparatus according to claim 1, wherein the chamber is mounted on an upper surface of a mounting apparatus, a lower part of the chamber being open and facing the upper surface of the mounting apparatus, and
the apparatus to test a semiconductor device further comprises:
a board mounted to the upper surface of the mounting apparatus to receive an electrical signal from a semiconductor device inside the chamber and to transmit an electrical signal to a device outside the chamber; and
sockets connected to the board to electrically connect the semiconductor devices to the board.

3. The apparatus according to claim 2, wherein the apparatus further comprises:
a rotary member connected to a side of the chamber and mounted to the mounting apparatus,
wherein the rotary member includes a first hinge end connected to the side of the chamber, a second hinge end mounted to the mounting apparatus, and a cylinder connecting the first hinge end to the second hinge end to longitudinally expand/contract by receiving an electrical signal from the control module.

4. The apparatus according to claim 3, wherein a lower end surface of the chamber is separated from the upper surface of the mounting apparatus by a gap.

5. The apparatus according to claim 1, wherein the temperature control apparatus comprises:
a hot air supplier to provide hot air heated to a certain temperature into the chamber; and
a cold air supplier to provide cold air cooled to a certain temperature into the chamber.

6. The apparatus according to claim 5, wherein the control module comprises a selector to selectively operate each of the hot air supplier and the cold air supplier.

7. The apparatus according to claim 5, wherein a reference temperature value is previously set in the control module, and
the control module operates the hot air supplier when a test temperature value is higher than the reference temperature value and operates the cold air suppler when the test temperature value is lower than the reference temperature value.

8. The apparatus according to claim 5, wherein:
the hot air supplier comprises:
a first air compressor to compress external air;
a housing to receive the compressed air from the first air compressor;
a suction pipe to connect the first air compressor to the housing;
a heater located in the housing and configured to receive an electrical signal from the control module to heat the compressed air to a predetermined temperature; and
an exhaust pipe to connect the housing to the interior of the chamber to provide the heated compressed air into the chamber from the housing; and
the cold air supplier comprises:
a second air compressor to compress external air; and
a vortex tube to receive the compressed air from the second air compressor to be rotated at a certain speed to form flow paths having different temperatures and to supply the compressed air cooled to a predetermined temperature into the chamber.

9. The apparatus according to claim 8, wherein:
the vortex tube comprises:
a vortex rotary chamber having a rotary space therein to rotate the compressed air introduced from the second air compressor at a certain rotational speed;
a compressed air supply pipe to introduce the compressed air from the second air compressor into the vortex rotary chamber;
a hot air discharge pipe to expose the rotary space of the vortex rotary chamber to the exterior of the chamber and to guide a first vortex stream generated by rotation from the rotary space;
an adjustment valve located at an end of the hot air discharge pipe and configured to receive an electrical signal from the control module to vary a discharge of the first vortex stream to the exterior of the chamber; and
a cold air discharge pipe to expose the rotary space of the vortex rotary chamber to the interior of the chamber and to guide a second vortex stream generated by rotation of the rotary space and directed in a different direction than the first vortex stream.

10. The apparatus according to claim 9, wherein:
the vortex tube further comprises:
a silencer located at an end of the discharge pipe,
wherein the silencer includes a silencer body having a flow hole with a diameter that is gradually reduced from the end of the discharge pipe to an air output end, and
the silencer comprises a sound-absorbing material.

11. The apparatus according to claim 8, further comprising:
a diffuser having a plurality of discharge holes an end of the discharge pipe inside the chamber,
wherein:
the discharge pipe is connected to a center part of the diffuser,
the discharge holes extend radially from the center part, and
the diameters of the discharge holes increase incrementally from the center part toward the outer edge of the diffuser.

12. The apparatus according to claim 8, further comprising:
a connection pipe connected to the exhaust pipe and the cold air discharge pipe; and
an opening valve connected between the connection pipe and the exhaust pipe to output one of hot air from the exhaust pipe and cold air from the cold air discharge pipe into the chamber.

13. A method of testing a semiconductor device comprising:
positioning a plurality of semiconductor devices within a chamber; and
performing a test by receiving an electrical signal from a control module to respectively heat and cool an inner space of the chamber using a temperature control apparatus connected to the chamber.

14. The method according to claim 13, wherein positioning the plurality of semiconductor devices comprises:
rotating and opening the chamber, which is mounted on an upper surface of a mounting apparatus, using a rotary member connected to the chamber and the upper surface of the mounting apparatus;
positioning the semiconductor devices on a board mounted on the upper surface of the mounting apparatus to electrically connect the semiconductor devices to the board; and
rotating and closing the chamber using the rotary member so that a certain gap exists between a lower surface of the chamber and the upper surface of the mounting apparatus to expose air inside the chamber to air outside the chamber.

15. The method according to claim 13, wherein the performing of the test comprises:
selecting one of a hot air supplier of the temperature control apparatus to provide hot air heated to a certain temperature into the chamber and a cold air supplier of the temperature control apparatus to provide cold air cooled to a certain temperature into the chamber using a selector electrically connected to the control module; and
setting a test temperature value of the inner space of the chamber using the control module and the selected hot air supplier or the cold air supplier.

16. The method according to claim 13, wherein the performing of the test comprises:
setting a reference temperature value using the control module, and
operating the hot air supplier of the temperature control apparatus to provide hot air heated to a certain temperature into the chamber when the set test temperature value is equal to or higher than the reference temperature value and operating the cold air supplier of the temperature control apparatus configured to provide cold air cooled to a certain temperature into the chamber when the test temperature value is equal to or lower than the reference temperature value, using the control module.

17. The method according to claim 15, wherein the hot air supplier comprises:
a first air compressor to compress external air;
a housing to receive the compressed air from the first air compressor;
a suction pipe to connect the first air compressor to the housing;
a heater positioned in the housing and configured to receive an electrical signal from the control module to heat the compressed air to a predetermined temperature; and
an exhaust pipe to connect the housing to the interior of the chamber to provide the heated compressed air into the chamber; and
the cold air supplier comprises:
a second air compressor to compress external air, and
a vortex tube to receive the compressed air from the second air compressor, the compressed air from the second air compressor to be rotated at a certain speed to form flow paths having different temperatures, the vortex tube to supply the compressed air cooled to a predetermined temperature into the chamber,
wherein:
the vortex tube includes:
a vortex rotary chamber having a rotary space in the chamber and configured to rotate the compressed air introduced from the second air compressor at a certain rotational speed;
a compressed air supply pipe to introduce the compressed air from the second air compressor into the vortex rotary chamber;
a hot air discharge pipe to expose the rotary space of the vortex rotary chamber to the exterior of the chamber and to guide a first vortex stream generated by rotation from the rotary space;
an adjustment valve located at an end of the hot air discharge pipe and configured to receive an electrical signal from the control module and to vary a discharge of the first vortex stream to the exterior of the chamber; and
a cold air discharge pipe to expose the rotary space of the vortex rotary chamber to the inner space of the chamber and to guide a second vortex stream generated by rotation of the rotary space and directed in a different direction than the first vortex stream,
wherein:
the cold air discharge pipe is connected to the exhaust pipe, and
an opening valve is located at a position where the discharge pipe is connected to the exhaust pipe, and
the opening valve outputs one of hot air from the exhaust pipe and cold air from the cold air discharge pipe into the chamber based upon an electrical signal from the control module

18. A semiconductor device test apparatus, comprising:
a chamber to receive at least one semiconductor device; and
a temperature control apparatus including a hot air supplier to supply hot air to the chamber and cold air supplier to supply cold air to the chamber,
wherein the hot air supplier only emits hot air into the chamber, and
the cold air supplier emits cold air into the chamber and hot air away from the chamber.

19. The semiconductor device test apparatus according to claim 18, wherein the chamber comprises:
an upper portion comprising side walls and a top; and
a lower portion including an upper surface of a mounting apparatus,
wherein:
the upper portion is mounted to the lower portion by a rotatable hinge, and
the upper portion is separated from the lower portion by a gap capable of passing air from inside the chamber to outside the chamber.

20. The semiconductor device test apparatus according to claim 19, wherein the temperature control apparatus comprises:
at least one air compressor; and
a diffuser to receive at least one of hot air and cold air from the hot air supplier and cold air supplier, respectively, and to output the hot air and cold air into the chamber,
wherein the hot air supplier comprises:
a housing having a heater therein to heat the air from the air compressor; and
an exhaust pipe to output the heated air from the housing into the chamber, and the cold air supplier comprises:
a vortex rotary device including a vortex air chamber to receive compressed air from the air compressor, to generate a plurality of air currents within the vortex rotary device, to output hot air outside the chamber, and to output cold air into the chamber.

21. The semiconductor device test apparatus according to claim 20, wherein the temperature control apparatus is mounted to the upper portion of the chamber.

22. The semiconductor device test apparatus according to claim 20, wherein the vortex rotary device includes a cold air discharge pipe, and
the temperature control apparatus further comprises:
a connection pipe to connect the cold air discharge pipe and the exhaust pipe; and
an air control valve to respectively output air from each of the hot air supplier and the cold air supplier into the chamber.

23. The semiconductor device test apparatus according to claim 20, wherein the semiconductor device test apparatus further comprises:
a sensor located inside the chamber to determine a temperature within the chamber; and
a controller to control operation of the hot air supplier and cold air supplier based upon the temperature within the chamber and predetermined test settings, and to control opening and closing of the chamber by controlling rotation of the rotatable hinge.
